(19) United States
(12) Patent Application Publication
(10) Pub. No.: US 2026/0246374 A1
(43) Pub. Date: Aug. 20, 2026

(54) MAGNETIC COMPONENT AND POWER CONVERSION MODULE

(71) Applicant: LITE-ON Technology Corporation, Taipei (TW)

(72) Inventors: De-Jia LU, Taipei (TW); Yao-Cheng TIEN, Taipei (TW); Han-Min HUANG, Taipei (TW); Cheng-Wei TSENG, Taipei (TW); Chen CHEN, Taipei (TW)

(21) Appl. No.: 19/287,835

(22) Filed: Aug. 1, 2025

Related U.S. Application Data
(60) Provisional application No. 63/758,377, filed on Feb. 14, 2025.

(30) Foreign Application Priority Data
Jun. 3, 2025 (CN) 2025107272202

(51) Int. Cl. H02M 3/00; H01F 27/06; H01F 27/28; H02M 1/14; H05K 1/16

(52) U.S. Cl. CPC H02M 3/003; H01F 27/06; H01F 27/2804; H01F 27/2828; H02M 1/14; H02M 3/01; H05K 1/165; H01F 2027/065; H01F 2027/2814; H05K 2201/086; H05K 2201/09163

(57) ABSTRACT

A magnetic component includes a substrate and a coil winding. The substrate includes a winding portion, a magnetic body is embedded in the winding portion, and a plurality of soldering pads are disposed on a surface of the substrate. The coil winding surrounds the winding portion and is arranged corresponding to the magnetic body, and two ends of the coil winding are respectively connected to two of the plurality of the soldering pads. Compared with the existing magnetic component with a multi-layer circuit board and planar windings in different layers of the multi-layer circuit board, the magnetic component includes the coil winding surrounding the winding portion in which the magnetic body is embedded, so that a DC resistance of the coil winding is not increased due to the limitation of the number of layers of the substrate, and a dimension in a horizontal plane direction can be reduced.

### CROSS REFERENCE TO RELATED PRESENT DISCLOSURE

This application claims the priority benefit of U.S. Provisional Patent Application Ser. No. 63/758,377, filed on Feb. 14, 2025, and Chinese Patent Application Serial Number 2025107272202, filed on Jun. 3, 2025, the full disclosures of which are incorporated herein by reference.

### TECHNICAL FIELD

The present disclosure relates to a magnetic component and a power conversion module, in particular to a magnetic component that does not cause a DC resistance of a coil winding to increase due to the limitation of the number of layers of a substrate and a power conversion module using the same.

### RELATED ART

The common architecture of the power conversion module can be a forward power conversion module or a flyback power conversion module. However, both the forward power conversion module and the flyback power conversion module comprise magnetic components (e.g., an inductor or a transformer).

The structure of existing inductors usually uses a multi-layer circuit board and planar windings arranged in different layers of the circuit board to achieve the number of windings required for the designed inductor. For example, when the inductor requires eight turns of planar winding to meet the design requirements, the circuit board of the inductor needs to have at least eight layers if one layer of the circuit board is provided with one turn of planar winding, or each layer of the circuit board needs to be provided with two turns of planar winding if the circuit board is limited to a four-layers circuit board. When the installation space for the windings is fixed and the number of planar windings per layer of the circuit board is doubled, the DC resistance of the winding of the inductor increases by two times.

Therefore, how to provide a magnetic component that can avoid the increase of the DC resistance of the winding due to the limitation of the number of layers of the circuit board and a power conversion module using the same is a problem that the industry in this technical field wants to solve.

### SUMMARY

The embodiments of the present disclosure provide a magnetic component and a power conversion module, which can solve the problem of the increase in the DC resistance of the winding due to the limitation of the number of board layers of the circuit board in the existing magnetic component using a multi-layer circuit board and planar windings arranged in different layers of the multi-layer circuit board.

In order to solve the above technical problems, the present disclosure is implemented as follows:

The present disclosure provides a magnetic component, which includes a substrate and a coil winding. The substrate includes a winding portion, a magnetic body is embedded in the winding portion, and a plurality of soldering pads are disposed on a surface of the substrate. The coil winding surrounds the winding portion and is arranged corresponding to the magnetic body, and two ends of the coil winding are respectively connected to two of the plurality of the soldering pads.

The present disclosure provides another magnetic component, which includes a substrate, magnetic body and a coil winding. The substrate includes a winding portion and a notch, and the winding portion is adjacent to the notch. The magnetic body is disposed in the winding portion of the substrate. The coil winding surrounds the winding portion and is arranged corresponding to the magnetic body, and a portion of the coil winding is disposed in the notch.

The present disclosure further provides a power conversion module, which includes a printed circuit board assembly and a magnetic component of the present disclosure, wherein the printed circuit board assembly includes a printed circuit board, and a substrate of the magnetic component of the present disclosure is a part of the printed circuit board.

In the magnetic component of the embodiments of the present disclosure, the coil winding surrounds the winding portion in which the magnetic body is embedded or the coil winding surrounds the winding portion in which the magnetic body is disposed, so that the DC resistance of the coil winding of the magnetic component is not affected by the number of layers of the substrate (equivalent to the circuit board) compared to the existing magnetic component that uses a multi-layer circuit board and planar windings arranged in different layers of the multi-layer circuit board. Therefore, the DC resistance of the coil winding of the magnetic component does not increase due to the limitation of the number of layers of the substrate. In addition, based on the arrangement of the coil winding that sleeves on (surrounds) the winding portion of the substrate, the dimension of the magnetic component of the embodiments of the present disclosure in the horizontal plane direction (i.e., the direction parallel to the surface of the substrate) can be reduced, so when the magnetic component of the embodiments of the present disclosure is applied to a power conversion module, it can reduce the layout space required for the power conversion module compared to the existing magnetic component that uses the multi-layer circuit board and planar windings arranged in different layers of the multi-layer circuit board, and is applied to the power conversion module.

### BRIEF DESCRIPTION OF THE DRAWINGS

Accompanying drawings described herein are intended to provide a further understanding of the present disclosure and form a part of the present disclosure, and exemplary embodiments of the present disclosure and descriptions thereof are intended to explain the present disclosure but are not intended to unduly limit the present disclosure. In the drawings:

FIG. 1 is a top view of a magnetic component according to a first embodiment of the present disclosure;

FIG. 2 is a schematic cross-sectional view along a line A-A′ in FIG. 1;

FIG. 3 is a top view of a magnetic component according to a second embodiment of the present disclosure;

FIG. 4 is an equivalent circuit diagram illustrating an LLC series resonant converter using the magnetic component of FIG. 1 as a resonant inductor;

FIG. 5 is a simulated waveform diagram for multiple signals of the resonant converter of FIG. 4;

FIG. 6 is a top view of a magnetic component according to a third embodiment of the present disclosure;

FIG. 7 is a top view of a magnetic component according to a fourth embodiment of the present disclosure;

FIG. 8 is a schematic cross-sectional view of a first embodiment along a line B-B′ in FIG.

FIG. 9 is a schematic cross-sectional view of a second embodiment along the line B-B′ in FIG. 7;

FIG. 10 is a schematic cross-sectional view of a third embodiment along the line B-B′ in FIG. 7;

FIG. 11 is a top view of a magnetic component according to a fifth embodiment of the present disclosure;

FIG. 12 is a top view of a magnetic component according to a sixth embodiment of the present disclosure;

FIG. 13 is a three-dimensional schematic diagram of an embodiment of a power conversion device using a magnetic component of the present disclosure;

FIG. 14 is a top view of the power conversion module of FIG. 13;

FIG. 15 is a partially exploded schematic view of the power conversion module of FIG. 13; and

FIG. 16 is a schematic cross-sectional view along a line C-C′ in FIG. 14.

### DETAILED DESCRIPTION OF THE EMBODIMENTS

The embodiments of the present disclosure will be described below in conjunction with the relevant drawings. Directional terms, such as “up,” “down,” “left,” “right,” “front,” “back,” and the like, mentioned in the following embodiments are merely for referring to directions of the accompanying drawings. Accordingly, the directional terms used herein to explain and understand the present disclosure, but not to limit the present disclosure. In the figures, the same reference numbers refer to the same or similar components or method flows.

It must be understood that the words “including”, “comprising” and the like used in this specification are used to indicate the existence of specific technical features, values, method steps, work processes, elements and/or components. However, it does not exclude that more technical features, values, method steps, work processes, elements, components, or any combination of the above can be added.

It must be understood that when an element is described as being “connected” or “coupled” to another element, it may be directly connected or coupled to another element, and intermediate elements therebetween may be present. In contrast, when an element is described as “directly connected” or “directly coupled” to another element, there is no intervening element therebetween. In addition, the terms such as “first”, “second”, and the like, are only used to distinguish elements described with the same technical terms, and do not represent the specific quantity or order.

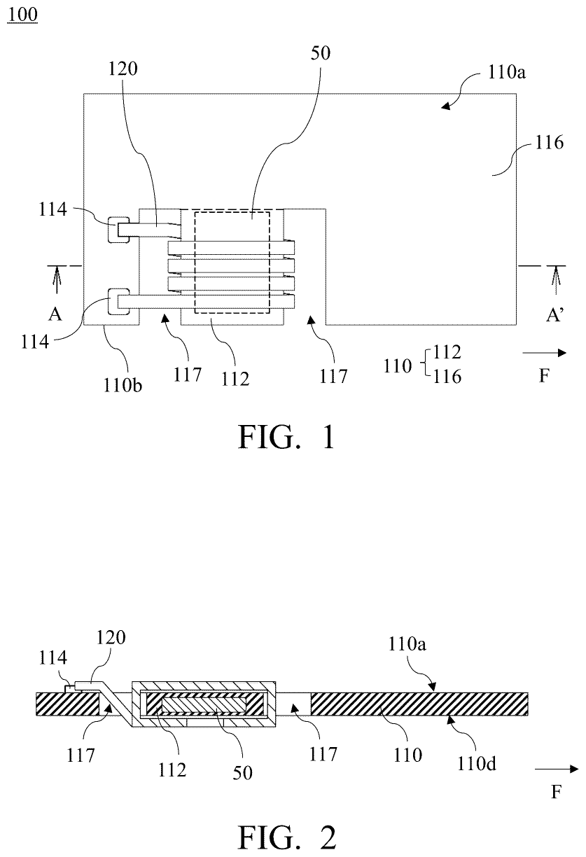

Please refer to FIG. 1 and FIG. 2, FIG. 1 is a top view of a magnetic component according to a first embodiment of the present disclosure, and FIG. 2 is a schematic cross-sectional view along a line A-A′ in FIG. 1. As shown in FIG. 1 and FIG. 2, a magnetic component 100 comprises a substrate 110 and a coil winding 120. The substrate 110 comprises a winding portion 112, and a magnetic body 50 is embedded in the winding portion 112. A plurality of soldering pads 114 are disposed on a surface 110a of the substrate 110. The coil winding 120 surrounds the winding portion 112 and is arranged corresponding to the magnetic body 50. Two ends of the coil winding 120 are respectively connected to two of the plurality of soldering pads 114. Among them, the magnetic component 100 may be an inductor; the substrate 110 may be, but not limited to, a glass substrate, a printed circuit board or a ceramic circuit board; a material of the magnetic body 50 may be, but not limited to, a metal magnetic material or a ferrite material, and the ferrite material may be, but not limited to, a power ferrite material, such as manganese-zinc ferrite materials of Anci Magnetics Corporation with models such as JPP-95, JPP-95A, JPP-97, and JPP-96, and manganese-zinc ferrite materials of DMEGC Magnetics Corporation with models such as DMR40, DMR44, and DMR47, and the material of the magnetic body 50 may be selected appropriately according to the actual requirements of the magnetic component 100; and the coil winding 120 may be made of, but not limited to, a round copper wire or a flat copper wire. It should be noted that, in order to avoid the drawing of FIG. 1 being too complicated, only two soldering pads 114 are drawn as representatives, and the actual number of soldering pads 114 can be adjusted according to actual needs; the portion of the coil winding 120 surrounding a surface 110d of the substrate 110 is arranged obliquely (the surface 110a and the surface 110d are opposite surfaces); the magnetic body 50 is embedded in the winding portion 112, so the magnetic body 50 in FIG. 1 is drawn with a dotted line.

In one embodiment, the substrate 110 comprises a substrate body 116 and the winding portion 112 extending from the substrate body 116. A side 110b of the substrate 110 has two notches 117 spaced apart along a first direction F, and the winding portion 112 extending from the substrate body 116 of the substrate 110 is located between the two notches 117 (as shown in FIG. 1). In other words, the magnetic component 100 comprises the substrate 110, the magnetic body 50 and the coil winding 120, the substrate 110 comprises the winding portion 112 and two notches 117, the winding portion 112 is adjacent to the notch 117, the two notches 117 are respectively located on opposite sides of the winding portion 112, the magnetic body 50 is embedded in the winding portion 112 of the substrate 110, the coil winding 120 surrounds the winding portion 112 and is arranged corresponding to the magnetic body 50, a portion of the coil winding 120 is disposed in one notch 117, and another portion of the coil winding 120 is disposed in another notch 117.

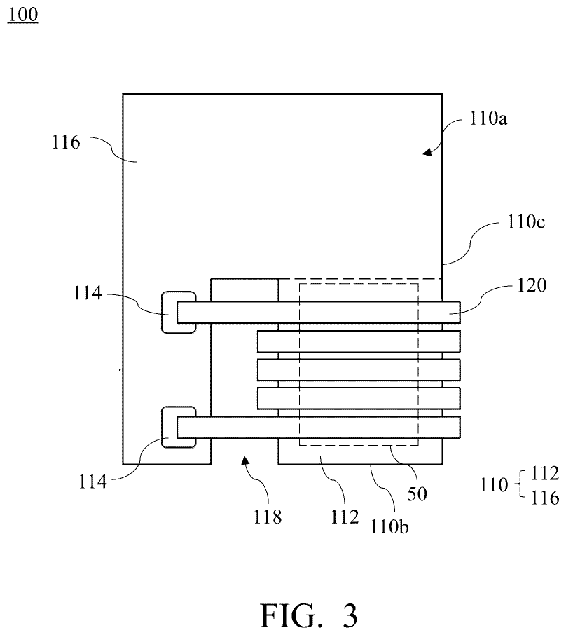

In another embodiment, the substrate 110 comprises the substrate body 116 and the winding portion 112 extending from substrate body 116. The side 110b of substrate 110 has a notch 118, and the winding portion 112 extending from substrate body 116 of substrate 110 is located between the notch 118 and an adjacent side 110c of substrate 110 adjacent to the side 110b of substrate 110 (as shown in FIG. 3, which is a top view of a magnetic component according to a second embodiment of the present disclosure). In other words, in the embodiment of FIG. 3, the magnetic component 100 comprises the substrate 110, the magnetic body 50 and the coil winding 120, the substrate 110 comprises the winding portion 112 and the notch 118, the winding portion 112 is adjacent to the notch 118, the magnetic body 50 is disposed in the winding portion 112 of the substrate 110, the coil winding 120 surrounds the winding portion 112 and is arranged corresponding to the magnetic body 50, and a portion of the coil winding 120 is disposed in the notch 118. Among them, the substrate 110 may further comprise two soldering pads 114, the two ends of the coil winding 120 are respectively connected to the two soldering pads 114, and the two soldering pads 114 are disposed on the same surface of the substrate 110 (i.e., the surface 110a).

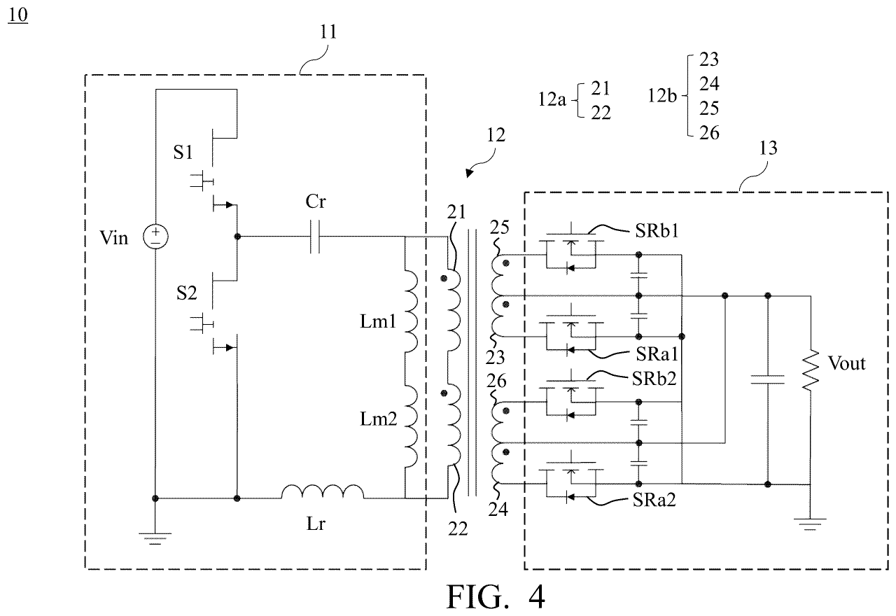

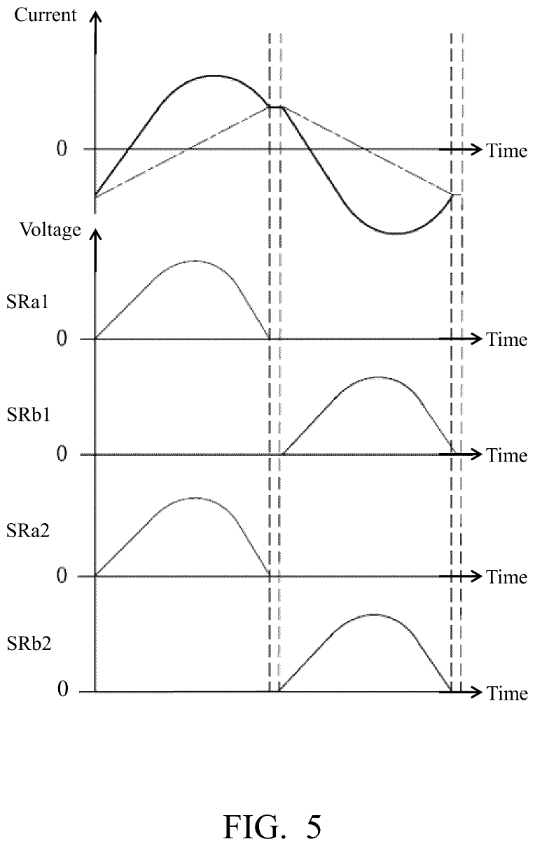

Please refer to FIG. 4 and FIG. 5, FIG. 4 is an equivalent circuit diagram illustrating an LLC series resonant converter using the magnetic component of FIG. 1 as a resonant inductor, and FIG. 5 is a simulated waveform diagram for multiple signals of the resonant converter of FIG. 4. As shown in FIG. 4, an LLC series resonant converter 10 comprises a switch circuit 11, a transformer 12 and a rectifier circuit 13, wherein the switch circuit 11 comprises an input voltage Vin, a first switch S1, a second switch S2, a magnetizing inductor Lm1, a magnetizing inductor Lm2, a resonant capacitor Cr and a resonant inductor Lr (i.e., the magnetic component 100 of FIG. 1). The transformer 12 comprises a primary-side winding 12a consisting of a first primary-side sub-winding 21 and a second primary-side sub-winding 22, and a secondary-side winding 12b consisting of a first secondary-side positive half-cycle sub-winding 23, a second secondary-side positive half-cycle sub-winding 24, a first secondary-side negative half-cycle sub-winding 25 and a second secondary-side negative half-cycle sub-winding 26. The rectifier circuit 13 comprises a rectifier switch SRa1, a rectifier switch SRa2, a rectifier switch SRb1, a rectifier switch SRb2 and an output terminal Vout. In FIG. 5, the top waveform diagram shows the waveform of the current flowing through the magnetizing inductor Lm2, which is indicated by a dotted line, and the waveform of the current flowing through the resonant inductor Lr, which is indicated by a solid line, where the vertical axis represents a current value. FIG. 5 also shows the waveforms of the voltages of the rectifier switch SRa1, the rectifier switch SRa2, the rectifier switch SRb1, and the rectifier switch SRb2, where the vertical axis represents a voltage value. It can be seen from FIG. 4 and FIG. 5 that the magnetic component 100 of FIG. 1 can be applied as the resonant inductor Lr of the LLC series resonant converter 10.

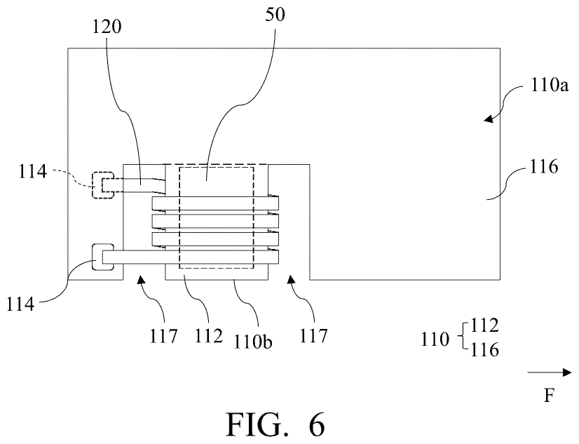

Please refer to FIG. 6, which is a top view of a magnetic component according to a third embodiment of the present disclosure. The difference between a magnetic component 100a of FIG. 6 and the magnetic component 100 of FIG. 3 lies in the configuration positions of the two soldering pads 114, and the two soldering pads 114 of the magnetic component 100a are disposed on two opposite surfaces of the substrate 110. It should be noted that, since FIG. 6 is a top view, one soldering pad 114 is shielded by the substrate 110 and is therefore drawn with a dotted line.

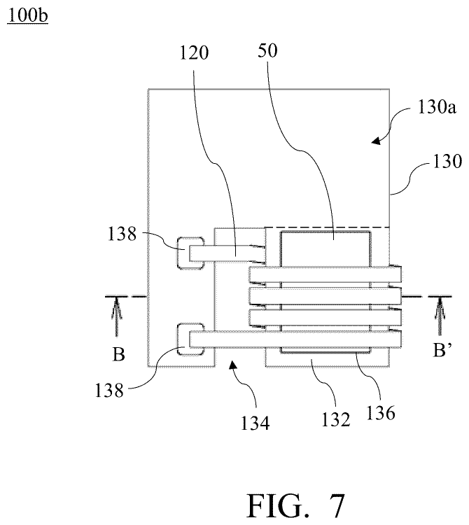

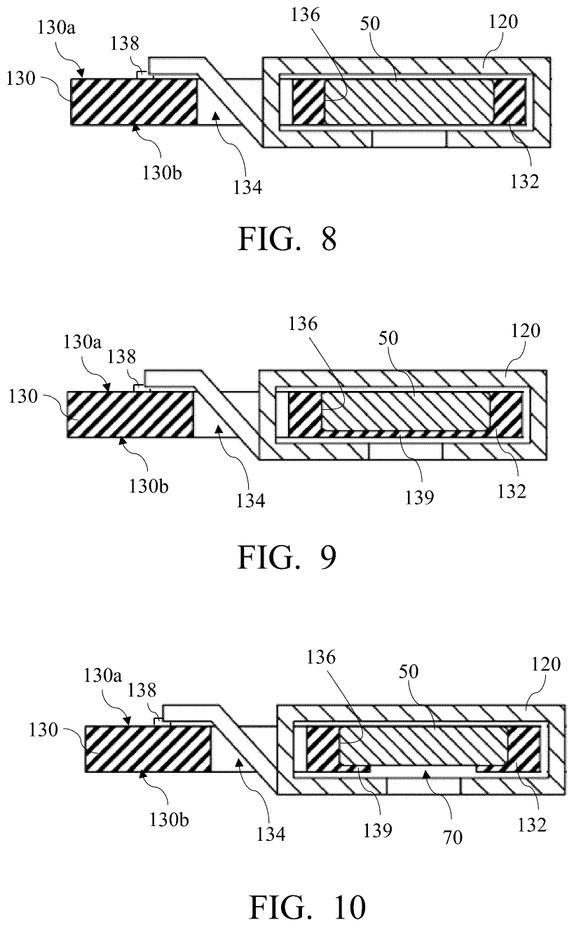

Please refer to FIG. 7 to FIG. 10, FIG. 7 is a top view of a magnetic component according to a fourth embodiment of the present disclosure, FIG. 8 is a schematic cross-sectional view of a first embodiment along a line B-B′ in FIG. 7, FIG. 9 is a schematic cross-sectional view of a second embodiment along the line B-B′ in FIG. 7, and FIG. 10 is a schematic cross-sectional view of a third embodiment along the line B-B′ in FIG. 7. As shown in FIG. 7 to FIG. 10, a magnetic component 100b comprises a substrate 130, a magnetic body 50 and a coil winding 120, the substrate 130 comprises a winding portion 132 and a notch 134, the winding portion 132 is adjacent to the notch 134, the magnetic body 50 is disposed in the winding portion 132 of the substrate 130, the coil winding 120 surrounds the winding portion 132 and is arranged corresponding to the magnetic body 50, and a portion of the coil winding 120 is disposed in the notch 134. Among them, the substrate 130 further comprises an accommodating portion 136, the magnetic body 50 is disposed in the accommodating portion 136, and the magnetic body 50 is exposed to a surface 130a of the substrate 130 to improve the heat dissipation effect. It should be noted that the portion of the coil winding 120 surrounding a surface 130b of the substrate 130 is arranged obliquely (the surface 130a and the surface 130b are opposite surfaces); and the magnetic body 50 is exposed to the surface 130a of the substrate 130, so the magnetic body 50 in FIG. 7 is drawn with a solid line. The substrate 130 may further comprise two soldering pads 138, two ends of the coil winding 120 are respectively connected to the two soldering pads 138, and the two soldering pads 138 are disposed on the same surface of the substrate 130 (i.e., the surface 130a).

In the embodiment of FIG. 8, the accommodating portion 136 may be a through hole, and the magnetic body 50 may be attached to the accommodating portion 136 by an adhesive material (not drawn), so that two opposite surfaces of the magnetic body 50 disposed in the accommodating portion 136 are exposed to the two opposite surfaces of the substrate 130 (i.e., the surface 130a and the surface 130b), wherein an opening area of the through hole on the surface 130a and an opening area of the through hole on the surface 130b may be the same or different.

In the embodiments of FIG. 9 and FIG. 10, the accommodating portion 136 may be a recessed portion of the substrate 130, and the magnetic body 50 may be attached to the accommodating portion 136 by an adhesive material (not drawn) and may be supported by the bottom surface of the recessed portion (i.e., a supporting portion 139). Among them, the supporting portion 139 of FIG. 10 is provided with a through hole 70, so that the two opposite surfaces of the magnetic body 50 are exposed to the two opposite surfaces of the substrate 130 (i.e., the surface 130a and the surface 130b), and the heat dissipation effect becomes better.

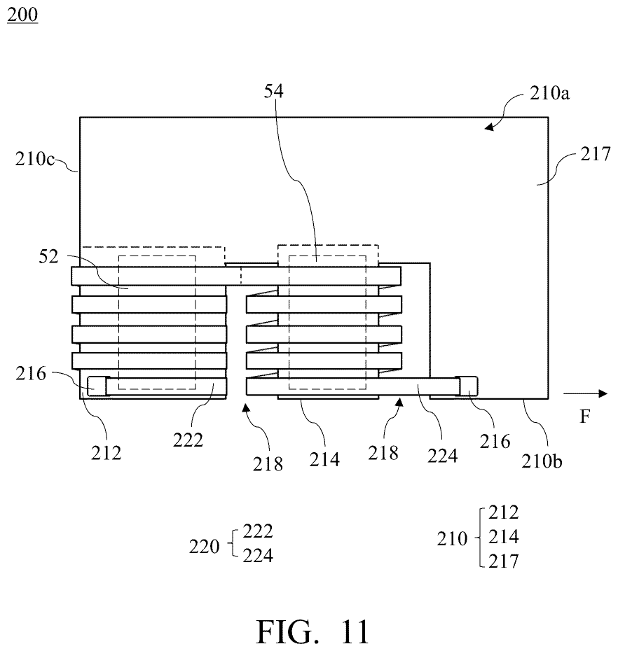

Please refer to FIG. 11, which is a top view of a magnetic component according to a fifth embodiment of the present disclosure. As shown in FIG. 11, a magnetic component 200 comprises a substrate 210 and a coil winding 220. The substrate 210 comprises a winding portion 212 and another winding portion 214 spaced apart from the winding portion 212 along a first direction F, the winding portion 212 is embedded with the magnetic body 52, and the another winding portion 214 is embedded with another magnetic body 54, and a plurality of soldering pads 216 are disposed on a surface 210a of the substrate 210. The coil winding 220 surrounds the winding portion 212 and the another winding portion 214, and is arranged corresponding to the magnetic body 52 and the another magnetic body 54. Two ends of the coil winding 220 are respectively connected to two of the plurality of soldering pads 216. Specifically, the coil winding 220 comprises a first winding 222 and a second winding 224 that are connected to each other (that is, one end of the first winding 222 is connected to one soldering pad 216, the other end of the first winding 222 is connected to one end of the second winding 224, and the other end of the second winding 224 is connected to the other soldering pad 216), the first winding 222 surrounds the winding portion 212 and is arranged corresponding to the magnetic body 52, and the second winding 224 surrounds the another winding portion 214 and is arranged corresponding to the another magnetic body 54. Among them, the magnetic component 200 may be two inductors connected in series, the substrate 210 may be, but not limited to, a glass substrate, a printed circuit board or a ceramic circuit board, the material of the magnetic body 52 and the magnetic body 54 may be, but not limited to, a metal magnetic material or a ferrite material, and the coil winding 220 may be made of, but not limited to, a round copper wire or a flat copper wire. It should be noted that, in order to avoid the drawing of FIG. 11 being too complicated, only two soldering pads 216 are drawn as a representative, and the actual number of soldering pads 216 can be adjusted according to actual needs.

In one embodiment, the substrate 210 comprises a substrate body 217, and the winding portion 212 and the another winding portion 214 extending from substrate body 217. A side 210b of the substrate 210 has two notches 218 spaced apart along the first direction F. The winding portion 212 extending from the substrate body 217 of the substrate 210 is located between an adjacent side 210c of the substrate 210 adjacent to the side 210b of the substrate 210 and the notch 218 adjacent to the adjacent side 210c, and the another winding portion 214 extending from the substrate body 217 of the substrate 210 is located between the two notches 218 (as shown in FIG. 11).

In one embodiment, the soldering pad 216 connected to one end of the coil winding 220 is located on the winding portion 212, and a projection area of the soldering pad 216, which is located on the winding portion 212 and is connected to one end of the coil winding 220, on the substrate 210 does not overlap with a projection area of the magnetic body 52 on the substrate 210 (as shown in FIG. 11).

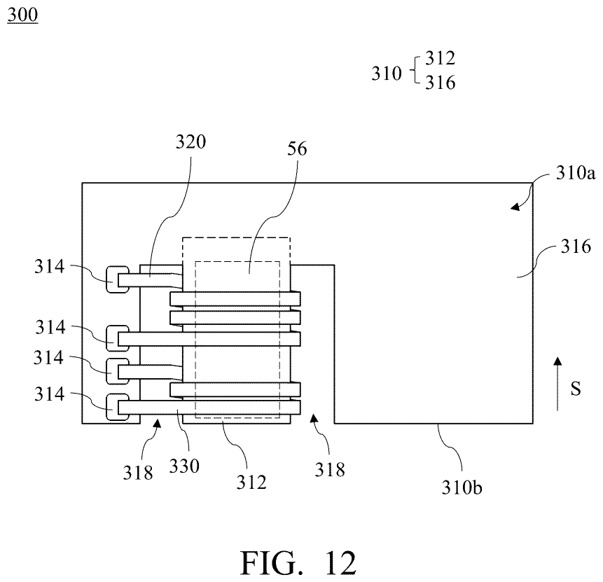

Please refer to FIG. 12, which is a top view of a magnetic component according to a sixth embodiment of the present disclosure. As shown in FIG. 12, a magnetic component 300 comprises a substrate 310, a coil winding 320 and another coil winding 330. The substrate 310 comprises a winding portion 312, the winding portion 312 is embedded with a magnetic body 56, and a surface 310a of the substrate 310 is provided with a plurality of soldering pads 314. The coil winding 320 surrounds the winding portion 312 and is arranged corresponding to the magnetic body 56, and two ends of the coil winding 320 are respectively connected to two of the plurality of soldering pads 314. The another coil winding 330 is spaced apart from the coil winding 320 along an extension direction S of the magnetic body 56, and the another coil winding 330 surrounds the winding portion 312 and is arranged corresponding to the magnetic body 56. Two ends of the another coil winding 330 are respectively connected to the other two of the plurality of soldering pads 314. Among them, the magnetic component 300 may be a transformer, the substrate 310 may be, but not limited to, a glass substrate, a printed circuit board or a ceramic circuit board, the material of the magnetic body 56 may be, but not limited to, a metal magnetic material or a ferrite material, and each of the coil winding 320 and the another coil winding 330 may be respectively made of, but not limited to, a round copper wire or a flat copper wire. It should be noted that, in order to avoid the drawing of FIG. 12 being too complicated, only four soldering pads 314 are drawn as a representative, and the actual number of soldering pads 314 can be adjusted according to actual needs.

In one embodiment, the substrate 310 comprises a substrate body 316 and the winding portion 312 extending from the substrate body 316. A side 310b of the substrate 310 has two notches 318 spaced apart along a first direction F, and the winding portion 312 extending from the substrate body 316 of the substrate 310 is located between the two notches 318 (as shown in FIG. 12).

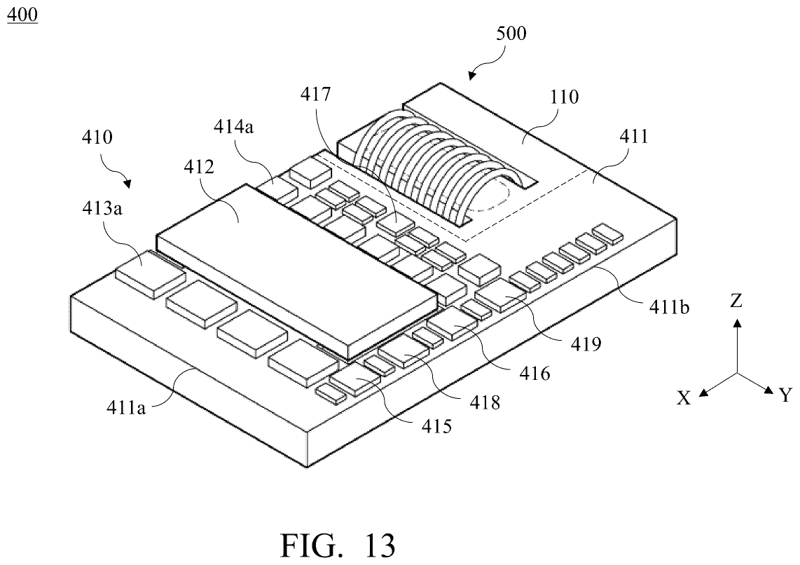

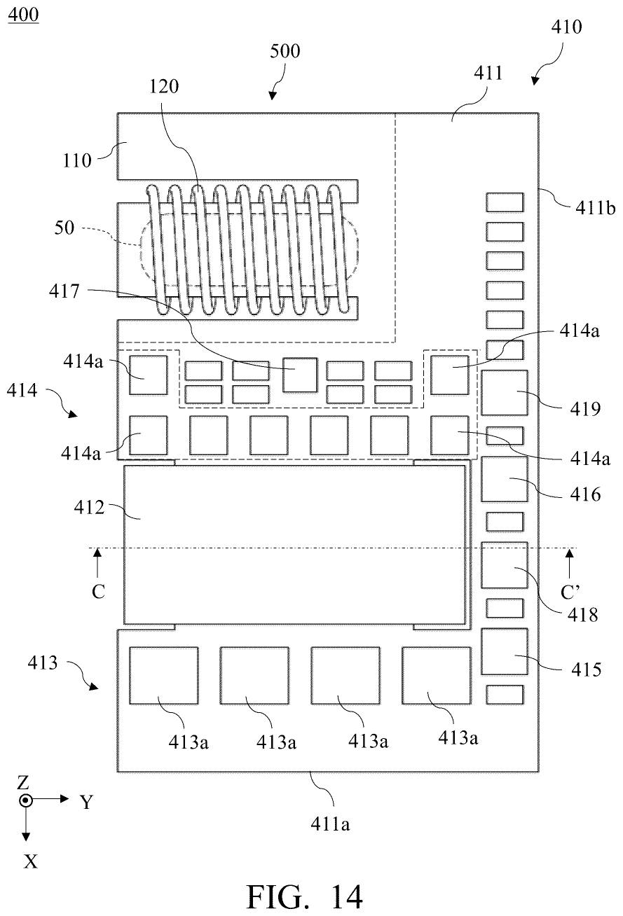

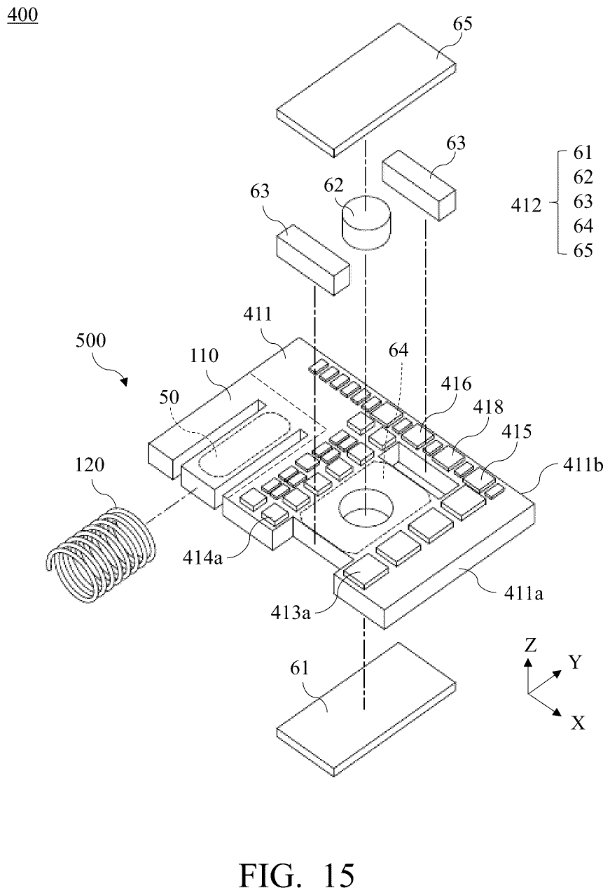

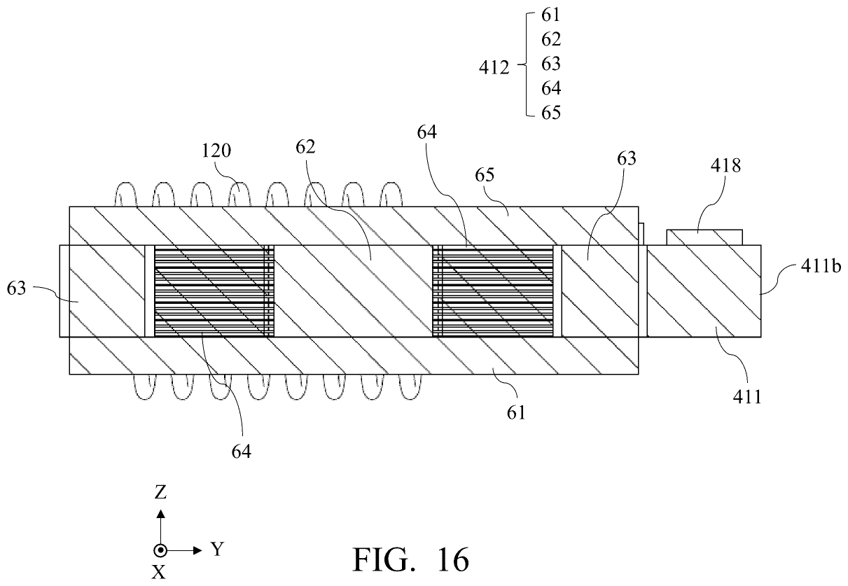

Please refer to FIG. 13 to FIG. 16, FIG. 13 is a three-dimensional schematic diagram of an embodiment of a power conversion device using a magnetic component of the present disclosure, FIG. 14 is a top view of the power conversion module of FIG. 13, FIG. 15 is a partially exploded schematic view of the power conversion module of FIG. 13, and FIG. 16 is a schematic cross-sectional view along a line C-C′ in FIG. 14. As shown in FIG. 13 to FIG. 16, a power conversion module 400 comprises a printed circuit board assembly 410 and a magnetic component 500, wherein the difference between magnetic component 500 and the magnetic component 100 in FIG. 1 lies in the configuration positions of the soldering pads 114. The soldering pads 114 of the magnetic component 500 may be disposed on the back side of the substrate 110 and therefore are not drawn in FIG. 13 to FIG. 15. The printed circuit board assembly 410 comprises a printed circuit board 411, the substrate 110 of the magnetic component 500 is a part of the printed circuit board 411. That is, the substrate 110 of the magnetic component 500 is a printed circuit board, and the substrate 110 of the magnetic component 500 is integrated into the printed circuit board 411 of the printed circuit board assembly 410. The power conversion module 400 may be, but is not limited to, a 1/4 brick type power module. A direction X is a length direction of the printed circuit board 411, a direction Y is a width direction of the printed circuit board 411, and a direction Z is a thickness direction of the printed circuit board 411. In this embodiment, the magnetic component 500 may be used as an output inductor of the power conversion module 400 to filter and stably output the current, but this embodiment is not intended to limit the present disclosure. For example, the magnetic component 200 may be used as two magnetizing inductors connected in series in the power conversion module 400, and the magnetic component 300 may be used as the transformer of the power conversion module 400.

In addition, the printed circuit board assembly 410 may further comprise a transformer 412 spaced apart from the magnetic component 500, a first switch module 413 disposed between the transformer 412 and a first side 411a of the printed circuit board 411, a second switch module 414 disposed between the transformer 412 and the magnetic component 500, a first driving module 415 and a second driving module 416 disposed between the transformer 412 and a second side 411b adjacent to the first side 411a, and a digital isolation integrated circuit 417 disposed between the second switch module 414 and the magnetic component 500. The transformer 412 may be configured to change a voltage level of an alternating current (AC). The transformer 412 may be a step-up transformer for increasing the voltage level or a step-down transformer for decreasing the voltage level. The first switch module 413 is electrically connected to the primary side of the transformer 412 and may comprise, but not limited to, four primary-side switch units 413a. The second switch module 414 is electrically connected to the secondary side of the transformer 412 and may comprise, but not limited to, eight secondary-side switch units 414a. The first driving module 415 is electrically connected to the first switch module 413 and configured to drive the first switch module 413. The first driving module 415 may comprise a power amplifier and an integrated circuit, wherein the power amplifier can drive the primary-side switch units 413a through low-power signals generated by the integrated circuit. The second driving module 416 is electrically connected to the second switch module 414 and configured to drive the second switch module 414. The second driving module 416 may comprise a power amplifier and an integrated circuit, wherein the power amplifier can drive the secondary-side switch units 414a through low-power signals generated by the integrated circuit. The digital isolation integrated circuit 417 is electrically connected to the first driving module 415 and the second driving module 416 to provide electrical isolation between the first driving module 415 and the second driving module 416 and allow digital signal communication between the first driving module 415 and the second driving module 416.

In addition, the printed circuit board assembly 410 may further comprise a first voltage regulator 418 and a second voltage regulator 419 disposed on opposite sides of the second driving module 416, and the first voltage regulator 418 is disposed between the second driving module 416 and the first driving module 415. Among them, the first voltage regulator 418 and the second voltage regulator 419 may be, but are not limited to, low dropout regulators (LDOs), and are configured to provide stable DC voltages respectively.

It should be noted that the electrical connection lines between any two of the magnetic component 500, the transformer 412, the first switch module 413, the second switch module 414, the first driving module 415, the second driving module 416, the digital isolation integrated circuit 417, the first voltage regulator 418 and the second voltage regulator 419 can be arranged inside the printed circuit board 411, so they are not drawn in FIG. 13 to FIG. 16.

In this embodiment, the transformer 412 may be, but not limited to, a planar magnetic component. Specifically, the transformer 412 may comprise a base plate 61, a magnetic column 62 disposed on the base plate 61, two supporting columns 63 disposed on the base plate 61 and located on opposite sides of the magnetic column 62, a plurality of planar windings 64 wound on the magnetic column 62, and a cover plate 65. Among them, the magnetic column 62 and the two supporting columns 63 penetrate the thickness of the printed circuit board 411 along the direction Z and are disposed between the bottom plate 61 and the cover plate 65, the plurality of planar windings 64 are embedded in the printed circuit board 411, and the plurality of planar windings 64 may comprise a plurality of primary-side windings, a plurality of secondary-side windings and/or a capacitor winding, but the present disclosure is not limited thereto. However, sufficient teachings, suggestions and implementation descriptions related to detailed technical features of the transformer 412 may be obtained based on common knowledge of this field and thus, will not be repeated.

In summary, in the magnetic component of the embodiments of the present disclosure, the coil winding surrounds the winding portion in which the magnetic body is embedded or the coil winding surrounds the winding portion in which the magnetic body is disposed, so that the DC resistance of the coil winding of the magnetic component is not affected by the number of layers of the substrate (equivalent to the circuit board) compared to the existing magnetic component that uses a multi-layer circuit board and planar windings arranged in different layers of the multi-layer circuit board. Therefore, the DC resistance of the coil winding of the magnetic component does not increase due to the limitation of the number of layers of the substrate. In addition, based on the arrangement of the coil winding that sleeves on (surrounds) the winding portion of the substrate, the dimension of the magnetic component of the embodiments of the present disclosure in the horizontal plane direction (i.e., the direction parallel to the surface of the substrate) can be reduced, so when the magnetic component of the embodiments of the present disclosure is applied to a power conversion module, it can reduce the layout space required for the power conversion module compared to the existing magnetic component that uses the multi-layer circuit board and planar windings arranged in different layers of the multi-layer circuit board, and is applied to the power conversion module.

While the present disclosure is disclosed in the foregoing embodiments, it should be noted that these descriptions are not intended to limit the present disclosure. On the contrary, the present disclosure covers modifications and equivalent arrangements obvious to those skilled in the art. Therefore, the scope of the claims must be interpreted in the broadest manner to comprise all obvious modifications and equivalent arrangements.

What is claimed is:

1. A magnetic component, comprising:
a substrate, comprising a winding portion, wherein a magnetic body is embedded in the winding portion, and a plurality of soldering pads are disposed on a surface of the substrate; and
a coil winding, surrounding the winding portion and arranged corresponding to the magnetic body, wherein two ends of the coil winding are respectively connected to two of the plurality of the soldering pads.

2. The magnetic component according to claim 1, wherein a side of the substrate has a notch, and the winding portion extending from a substrate body of the substrate is located between the notch and an adjacent side adjacent to the side.

3. The magnetic component according to claim 1, wherein a side of the substrate has two notches spaced apart along a first direction, and the winding portion extending from a substrate body of the substrate is located between the two notches.

4. The magnetic component according to claim 1, wherein the magnetic component further comprises another winding portion spaced apart from the winding portion along a first direction, and another magnetic body is embedded in the another winding portion; the coil winding comprises a first winding and a second winding connected to each other, the first winding surrounds the winding portion and is arranged corresponding to the magnetic body, and the second winding surrounds the another winding portion and is arranged corresponding to the another magnetic body.

5. The magnetic component according to claim 4, wherein a side of the substrate has two notches spaced apart along the first direction, the winding portion extending from a substrate body of the substrate is located between an adjacent side adjacent to the side and the notch adjacent to the adjacent side, and the another winding portion extending from the substrate body is located between the two notches.

6. The magnetic component according to claim 5, wherein the soldering pad connected to one end of the coil winding is located on the winding portion, and a projection area of the soldering pad, which is located on the winding portion and is connected to the one end of the coil winding, on the substrate does not overlap with a projection area of the magnetic body on the substrate.

7. The magnetic component according to claim 1, wherein the magnetic component further comprises another coil winding surrounding the winding portion; the another coil winding and the coil winding are spaced apart along an extension direction of the magnetic body and are arranged corresponding to the magnetic body; and two ends of the another coil winding are respectively connected to the other two of the plurality of the soldering pads.

8. The magnetic component according to claim 1, wherein the coil winding is made of a round copper wire or a flat copper wire.

9. The magnetic component according to claim 1, wherein the substrate is a glass substrate, a printed circuit board or a ceramic circuit board.

10. A power conversion module, comprising:
a printed circuit board assembly, comprising a printed circuit board; and
the magnetic component according to claim 1, wherein the substrate is a part of the printed circuit board.

11. The power conversion module according to claim 10, wherein the printed circuit board assembly further comprises a transformer spaced apart from the magnetic component, a first switch module disposed between the transformer and a first side of the printed circuit board, a second switch module disposed between the transformer and the magnetic component, a first driving module and a second driving module disposed between a second side adjacent to the first side and the transformer, and a digital isolation integrated circuit disposed between the second switch module and the magnetic component; the first switch module is electrically connected to a primary side of the transformer, the second switch module is electrically connected to a secondary side of the transformer, the first driving module is electrically connected to the first switch module and configured to drive the first switch module, the second driving module is electrically connected to the second switch module and configured to drive the second switch module, and the digital isolation integrated circuit is electrically connected to the first driving module and the second driving module to provide electrical isolation between the first driving module and the second driving module and allow digital signal communication between the first driving module and the second driving module.

12. The power conversion module according to claim 11, wherein the printed circuit board assembly further comprises a first voltage regulator and a second voltage regulator disposed on opposite sides of the second driving module, the first voltage regulator is disposed between the second driving module and the first driving module, and the first voltage regulator and the second voltage regulator are configured to provide stable DC voltages respectively.

13. The power conversion module according to claim 11, wherein the magnetic component is an output inductor for filtering and stably outputting a current.

14. A magnetic component, comprising:
a substrate comprising a winding portion and a notch, wherein the winding portion is adjacent to the notch;
a magnetic body disposed in the winding portion of the substrate; and
a coil winding surrounding the winding portion and arranged corresponding to the magnetic body, wherein a portion of the coil winding is disposed in the notch.

15. The magnetic component according to claim 14, wherein the substrate further comprises two soldering pads, two ends of the coil winding are respectively connected to the two soldering pads, and the two soldering pads are disposed on the same surface of the substrate.

16. The magnetic component according to claim 14, wherein the substrate further comprises two soldering pads, two ends of the coil winding are respectively connected to the two soldering pads, and the two soldering pads are disposed on two opposite surfaces of the substrate.

17. The magnetic component according to claim 14, wherein the substrate further comprises another notch, the another notch and the notch are respectively located on opposite sides of the winding portion, and another portion of the coil winding is disposed in the another notch.

18. The magnetic component according to claim 14, wherein the substrate further comprises an accommodating portion, the magnetic body is disposed in the accommodating portion, and the magnetic body is exposed to a surface of the substrate.
